(19) United States
(12) Patent Application Publication
(10) Pub. No.: US 2016/0155750 A1
(43) Pub. Date: Jun. 2, 2016

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventor: Naoki YASUDA, Mie (JP)

(73) Assignee: Kabushiki Kaisha Toshiba, Minato-ku (JP)

(21) Appl. No.: 14/642,115

(22) Filed: Mar. 9, 2015

Related U.S. Application Data
(60) Provisional application No. 62/085,408, filed on Nov. 28, 2014.

(51) Int. Cl. H01L 27/115; H01L 21/28; H01L 21/02; H01L 29/51

(52) U.S. Cl. CPC H01L 27/11582; H01L 29/513; H01L 29/518; H01L 29/517; H01L 21/28282; H01L 21/02164; H01L 21/0217; H01L 21/0223; H01L 21/02178; H01L 21/02252

(57) ABSTRACT

According to one embodiment, a semiconductor memory device includes a multilayer body, a semiconductor body, a charge accumulation film, a top oxide film, a silicon nitrogen-containing film, a bottom oxide film, and a block insulating film. The multilayer body includes a plurality of electrode films separately stacked each other and a plurality of interelectrode insulating films disposed between the plurality of electrode films. The semiconductor body that penetrates the multilayer body, extends in stacking direction of the multilayer body. The silicon nitrogen-containing film provides between the semiconductor body and the interelectrode insulating film and between the semiconductor body and the top oxide film and containing silicon and nitrogen. In the silicon nitrogen-containing film, thickness of a portion located between the electrode film and the body is thinner than thickness of a portion located between the interelectrode insulating film and the body.

### CROSS-REFERENCE TO RELATED APPLICATIONS

This application is based upon and claims the benefit of priority from U.S. Provisional Patent Application 62/085,408, filed on Nov. 28, 2014; the entire contents of which are incorporated herein by reference.

### FIELD

Embodiments described herein relate generally to a semiconductor memory device and a method for manufacturing the same.

### BACKGROUND

Three-dimensional multilayer semiconductor memory devices including memory cells stacked on a substrate have been proposed in recent years. In some of the three-dimensional multilayer semiconductor memory devices, a MONOS (metal oxide nitride oxide semiconductor) transistor is used as a memory cell. The MONOS transistor is formed by stacking a block insulating film, a charge accumulation film, and a tunnel insulating film sequentially from the control gate electrode side between the control gate electrode and the silicon channel material. Furthermore, it is desired to improve the hole injection efficiency to enhance erasure characteristics. To this end, it has also been proposed to form the tunnel insulating film in the MONOS transistor from a three-layer film composed of a silicon oxide layer, a silicon nitride layer, and a silicon oxide layer instead of a single silicon oxide film. In such semiconductor memory devices, it is desired to enhance data retention characteristics of memory cells.

### BRIEF DESCRIPTION OF THE DRAWINGS

FIG. 1 is a sectional view illustrating a semiconductor memory device according to an embodiment;

FIG. 2 is an enlarged view of portion A shown in FIG. 1 of the semiconductor memory device according to the embodiment;

FIGS. 3 and 4 are process sectional views illustrating the method for manufacturing the semiconductor memory device according to the embodiment; and

FIGS. 5 to 11 are process sectional views illustrating the method for manufacturing the semiconductor memory device according to the embodiment. FIGS. 5 to 11 show the region corresponding to portion B shown in FIG. 4.

### DETAILED DESCRIPTION

In general, according to one embodiment, a semiconductor memory device includes a multilayer body, a semiconductor body, a charge accumulation film, a top oxide film, a silicon nitrogen-containing film, a bottom oxide film, and a block insulating film. The multilayer body includes a plurality of electrode films separately stacked each other and a plurality of interelectrode insulating films disposed between the plurality of electrode films. The semiconductor body that penetrates the multilayer body, extends in stacking direction of the multilayer body. The charge accumulation film provides between the semiconductor body and the electrode film. The top oxide film provides between the semiconductor body and the charge accumulation film and containing silicon and oxygen. The silicon nitrogen-containing film provides between the semiconductor body and the interelectrode insulating film and between the semiconductor body and the top oxide film and containing silicon and nitrogen. The bottom oxide film provides between the semiconductor body and the silicon nitrogen-containing film and containing silicon and oxygen. The block insulating film provides between the electrode film and the charge accumulation film. In the silicon nitrogen-containing film, thickness of a portion located between the electrode film and the body is thinner than thickness of a portion located between the interelectrode insulating film and the body.

Embodiments of the invention will now be described with reference to the drawings.

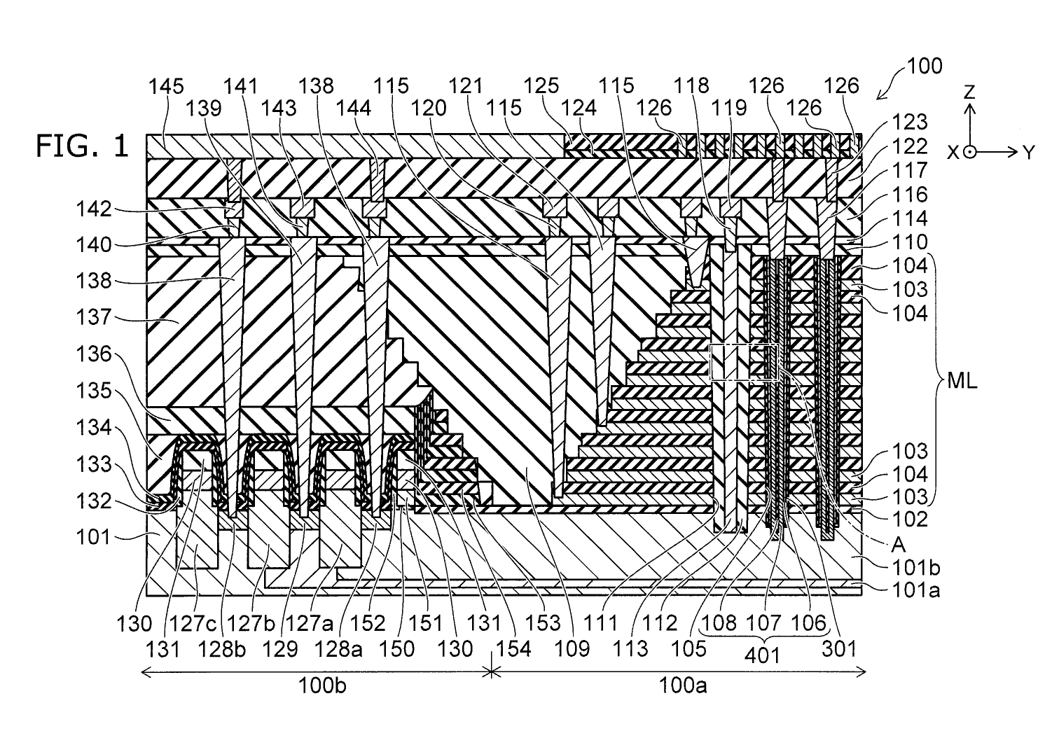

FIG. 1 is a sectional view illustrating a semiconductor memory device 100 according to an embodiment.

A memory cell region 100a and a peripheral transistor region 100b are defined in the semiconductor memory device 100 according to this embodiment. Multilayer memory cells are placed in the memory cell region 100a. Peripheral transistors are placed in the peripheral transistor region 100b.

As shown in FIG. 1, the semiconductor memory device 100 according to the embodiment includes a semiconductor substrate 101. The semiconductor substrate 101 is made of silicon. The conductivity type of the semiconductor substrate 101 is e.g. p⁻-type.

In the following, for convenience of description, an XYZ orthogonal coordinate system is introduced in this specification. In this coordinate system, two directions parallel to the major surface of the semiconductor substrate 101 and orthogonal to each other are referred to as X-direction and Y-direction. The direction orthogonal to both the X-direction and the Y-direction, i.e., the stacking direction of the layers, is referred to as Z-direction.

First, the configuration of the memory cell region 100a of the semiconductor memory device 100 according to the embodiment is described.

In the memory cell region 100a, an impurity layer 101a is provided on part of the semiconductor substrate 101. The conductivity type of the impurity layer 101a is n-type. An impurity layer 101b is provided on part of the impurity layer 101a. The conductivity type of the impurity layer 101b is p-type. The impurity layer 101a and the impurity layer 101b are in contact with each other.

An interlayer insulating film 102 is provided on the impurity layer 101b. A multilayer body ML is provided on the interlayer insulating film 102. Electrode films 103 and interelectrode insulating films 104 are alternately stacked in the multilayer body ML. The multilayer body ML is provided in e.g. 20 layers by alternately stacking electrode films 103 and interelectrode insulating films 104. Furthermore, a memory hole 105 is formed through the multilayer body ML and the interlayer insulating film 102. The memory hole 105 reaches the upper part of the impurity layer 101b. In the memory hole 105, a tunnel insulating film 301 and a semiconductor film 106 are provided sequentially from the side surface of the memory hole 105. Furthermore, a semiconductor film 107 is provided on the side surface of the semiconductor film 106 in the memory hole 105 and on the bottom surface of the memory hole 105. Moreover, a core oxide material 108 is provided on the side surface of the semiconductor film 107 in the memory hole 105. In the memory hole 105, the semiconductor films 106, 107 and the core oxide material 108 constitute a pillar 401.

A block insulating film 201 and a charge accumulation film 202 are provided in the region between the electrode film 103 and the interelectrode insulating film 104. However, the block insulating film 201 and the charge accumulation film 202 are not shown in FIG. 1 for simplicity of illustration.

The tunnel insulating film 301 is formed from a top oxide film 203, a cover oxide film 205, a silicon nitrogen-containing film 206, and a bottom oxide film 207. The top oxide film 203, the cover oxide film 205, the silicon nitrogen-containing film 206, and the bottom oxide film 207 are not shown in FIG. 1 for simplicity of illustration. The structure of these films will be described later.

On the peripheral transistor region 100b side of the multilayer body ML, the Y-direction length of the electrode film 103 and the interelectrode insulating film 104 provided on the upper surface thereof is made shorter stepwise for every two layers from the lower layer toward the upper layer. Thus, the end part on the peripheral transistor region 100b side of the multilayer body ML is formed in a staircase shape.

An interlayer insulating film 109 is provided in the region on the upper surface of the interlayer insulating film 102 on which the multilayer body ML is not provided. The interlayer insulating film 109 also covers the staircase-shaped end part of the multilayer body ML. In the Z-direction, the Z-direction position of the interlayer insulating film 109 is comparable to the Z-direction position of the upper surface of the uppermost layer of the multilayer body ML.

An insulating film 110 is provided on the upper surface of the multilayer body ML and on the upper surface of the interlayer insulating film 109. A slit 111 is formed through the insulating film 110, the multilayer body ML, and the interlayer insulating film 102. The slit 111 reaches the upper part of the impurity layer 101b. An insulating film 112 is provided on the side surface of the slit 111. A conductive material 113 is embedded inside the slit 111.

An insulating film 114 is provided on the insulating film 110. A plurality of contacts 115 are provided through the insulating films 114, 110 and the interlayer insulating film 109. Each contact 115 also penetrates through the interelectrode insulating film 104 in the staircase-shaped portion of the multilayer body ML. The contact 115 is in contact with the electrode film 103 of the corresponding stair.

An insulating film 116 is provided on the insulating film 114. A plug 117 is provided directly above the memory hole 105. The plug 117 penetrates through the insulating films 116, 114, and 110. The plug 117 is in contact with the semiconductor films 106, 107 and the core oxide material 108.

A plug 118 is provided directly above the slit 111. The plug 118 penetrates through the insulating film 114 and the lower part of the insulating film 116. The plug 118 is in contact with the conductive material 113. A source line 119 extending in the X-direction is provided directly above the plug 118 in the upper part of the insulating film 116. The source line 119 is connected to the conductive material 113 through the plug 118.

A plug 120 is provided directly above the contact 115 in the lower part of the insulating film 116. The plug 120 is in contact with the contact 115. A wiring 121 extending in the X-direction is provided directly above the plug 120 in the upper part of the insulating film 116.

An insulating film 122 is provided on the insulating film 116. A plug 123 penetrating through the insulating film 122 is provided directly above the plug 117 in the insulating film 122. The plug 123 is in contact with the plug 117.

An insulating film 124 is provided on the insulating film 122. An insulating film 125 is provided on the insulating film 124.

A bit line 126 extending in the X-direction is provided directly above the plug 123 in the insulating film 124 and the insulating film 125.

Next, the configuration of the peripheral transistor region 100b is described.

The impurity layers 101a and 101b are provided on part of the semiconductor substrate 101. The impurity layers 101a and 101b are provided continuously from the memory cell region 100a. The impurity layer 101a covers the lower surface of the impurity layer 101b and the side surface thereof on the peripheral transistor region 100b side.

A device isolation film 127a is provided between the upper part of the impurity layer 101a and the upper part of the impurity layer 101b. A device isolation film 127b is provided between the upper part of the impurity layer 101a and the upper part of the semiconductor substrate 101. Furthermore, a device isolation film 127c is provided in part of the upper part of the semiconductor substrate 101. The device isolation films 127a, 127b, and 127c are spaced from each other.

A diffusion layer 128a is provided on part of the impurity layer 101b on the memory cell region 100a side as viewed from the device isolation film 127a. The conductivity type of the diffusion layer 128a is p⁺-type. The diffusion layer 128a is provided in contact with the side surface of the device isolation film 127a. A diffusion layer 129 is provided between the device isolation film 127a and the device isolation film 127b. The conductivity type of the diffusion layer 129 is n⁺-type. Furthermore, a diffusion layer 128b is provided between the device isolation film 127b and the device isolation film 127c. The conductivity type of the diffusion layer 128b is p⁺-type.

A conductive film 130 is provided on the device isolation films 127a, 127b, and 127c. An insulating film 131 is provided on the conductive film 130. Furthermore, an insulating film 132 covers the side surface of the conductive film 130 and the insulating film 131. The insulating film 132 also covers the side surface of the upper part of the device isolation film 127. An insulating film 150 is provided directly above the region between the diffusion layer 128a on the memory cell region 100a side and the memory cell region 100a. A conductive film 151, the conductive film 130, and the insulating film 131 are provided sequentially from the lower layer on the insulating film 150. Furthermore, an insulating film 152 covers the side surface on the peripheral transistor region 100b side of the conductive films 151, 130 and the insulating film 131. Furthermore, an insulating film 133 covers the upper surface of the semiconductor substrate 101, the side surface of the insulating film 132, the upper surface of the insulating film 131, and the upper surface of the diffusion layers 128a, 128b, and 129. An insulating film 134 is provided on the insulating film 133. Here, the insulating films 133 and 134 are shaped like a valley in the portion in which the insulating film 133 is in contact with the upper surface of the semiconductor substrate 101 and the upper surface of the diffusion layers 128a, 128b, and 129. An interlayer insulating film 135 is embedded in the valley-shaped portion on the insulating film 134. An insulating film 136 is provided on the upper surface of the insulating film 134 and on the upper surface of the interlayer insulating film 135. An interlayer insulating film 137 is provided on the insulating film 136. Furthermore, an insulating film 153 covers the side surface on the memory cell region 100a side of the conductive films 151, 130, the insulating films 131, 133, 134, and 136 on the insulating film 150. The insulating film 153 also covers the upper surface of the interlayer insulating film 102 in the peripheral transistor region 100b. An insulating film 154 is provided on the insulating film 153. The insulating films 153 and 154 are provided in e.g. four layers on the insulating film 154.

The interlayer insulating film 109 is embedded between the multilayer body ML on one hand and the interlayer insulating film 137 and the insulating films 153 and 154 on the other provided in the memory cell region 100a.

The insulating films 110 and 114 are provided continuously from the memory cell region 100a on the interlayer insulating films 109 and 137.

A contact 138 is provided directly above the diffusion layers 128a and 128b. The contact 138 penetrates through the insulating films 114, 110, the interlayer insulating film 137, the insulating film 136, the interlayer insulating film 135, and the insulating films 134, 133.

A contact 139 is provided directly above the diffusion layer 129. The contact 139 penetrates through the insulating films 114, 110, the interlayer insulating film 137, the insulating film 136, the interlayer insulating film 135, and the insulating films 134, 133.

The insulating film 116 is provided continuously from the memory cell region 100a on the insulating film 114. A plug 140 is provided directly above the contact 138 in the lower part of the insulating film 116. A plug 141 is provided directly above the contact 139 in the lower part of the insulating film 116.

A wiring 142 extending in the X-direction is provided directly above the plug 140 in the upper part of the insulating film 116. A wiring 143 extending in the X-direction is provided directly above the plug 141 in the lower part of the insulating film 116.

The insulating film 122 is provided continuously from the memory cell region 100a on the insulating film 116.

A plug 144 is provided directly above the wiring 142 in the insulating film 122. A wiring 145 extending in the Y-direction is provided on the insulating film 122.

Next, the configuration of the multilayer body ML and around the memory hole 105 in the memory cell region 100a is described.

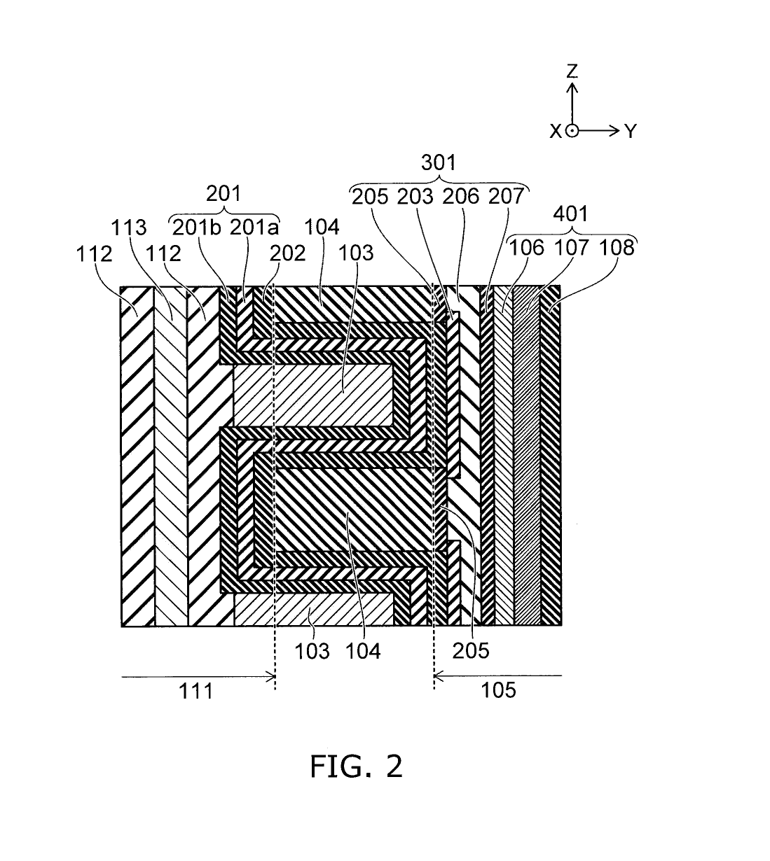

FIG. 2 is an enlarged view of portion A shown in FIG. 1 of the semiconductor memory device 100 according to the embodiment.

As shown in FIG. 2, a charge accumulation film 202 is provided between the memory hole 105 and the slit 111 in the multilayer body ML. The charge accumulation film 202 is placed in a zigzag shape in the cross section shown in FIG. 2. More specifically, the charge accumulation film 202 is placed on the side surface on the memory hole 105 side of the first electrode film 103. The charge accumulation film 202 passes between the first electrode film 103 and the interelectrode insulating film 104 and is extracted toward the slit 111. The charge accumulation film 202 passes on the side surface on the slit 111 side of the interelectrode insulating film 104. The charge accumulation film 202 passes between the interelectrode insulating film 104 and the second electrode film 103 and returns to the memory hole 105 side. The charge accumulation film 202 passes on the side surface on the memory hole 105 side of the second electrode film 103. By repeating this pattern, the charge accumulation film 202 extends as a whole in the Z-direction while coming close to and away from the memory hole 105. The charge accumulation film 202 is a film capable of retaining charge. The charge accumulation film 202 is formed from an insulating film such as silicon nitride film.

A block insulating film 201 is provided on the surface on the slit 111 side of the charge accumulation film 202. The block insulating film 201 is a layer passing substantially no current even under voltage application within the range of the driving voltage of the semiconductor memory device 100. The block insulating film 201 is formed from e.g. two layers, i.e., an insulating layer 201a made of silicon oxide and an insulating layer 201b made of alumina. Here, the insulating layer 201a is provided on the surface on the slit 111 side of the charge accumulation film 202. The insulating layer 201b is provided on the surface on the slit 111 side of the insulating layer 201a.

A cover oxide film 205 made of silicon oxide is provided on the side surface of the interelectrode insulating film 104 in the memory hole 105. A top oxide film 203 made of silicon oxide is provided on the side surface of the charge accumulation film 202 in the memory hole 105. In the foregoing, the insulating layer 201a is described as being made of silicon oxide. However, the insulating layer 201a is not limited thereto, but may be made of any material having high barrier height. Likewise, the insulating layer 201b is described as being made of alumina. However, the insulating layer 201b is not limited thereto, but may be made of any material capable of reducing electric field. That is, the film configuration has high blocking capability for both writing and erasure. In other words, this configuration can suppress leakage current due to electrons for both writing and erasure. Thus, both write saturation and erase saturation can be made less likely to occur.

A silicon nitrogen-containing film 206 is provided on the side surface of the interelectrode insulating film 104 in the memory hole 105, and more particularly on the side surface of the cover oxide film 205 and the top oxide film 203. The silicon nitrogen-containing film 206 is made of silicon nitride or silicon oxynitride. A bottom oxide film 207 made of silicon oxide is provided on the side surface of the silicon nitrogen-containing film 206 in the memory hole 105. The top oxide film 203, the cover oxide film 205, the silicon nitrogen-containing film 206, and the bottom oxide film 207 constitute a tunnel insulating film 301. The tunnel insulating film 301 is normally insulative. However, the tunnel insulating film 301 is a film passing a tunnel current upon application of a prescribed voltage within the range of the driving voltage of the semiconductor memory device 100.

Semiconductor films 106 and 107 are provided on the side surface of the bottom oxide film 207 in the memory hole 105. The semiconductor films 106 and 107 are formed from e.g. a semiconductor material such as silicon. A core oxide material 108 is provided on the side surface of the semiconductor film 107. The position of the core oxide material 108 is a position including the central axis of the memory hole 105.

The electrode film 103, the semiconductor films 106, 107, the block insulating film 201, the charge accumulation film 202, and the tunnel insulating film 301 constitute a memory cell transistor at the crossing portion of the pillar 401 and the electrode film 103. The electrode film 103 constitutes a select gate electrode. The pillar 401 is connected between the source line and the bit line. A plurality of memory cell transistors arranged in the Z-direction in and around the pillar 401 form one NAND string.

In the silicon nitrogen-containing film 206, the thickness of the portion located between the electrode film 103 and the bottom oxide film 207 is thinner than the thickness of the portion located between the interelectrode insulating film 104 and the bottom oxide film 207. For instance, the film thickness of the semiconductor film 106 is 15 nm. The film thickness of the bottom oxide film 207 is 1.5 nm. The film thickness of the cover oxide film 205 is 4 nm. In the silicon nitrogen-containing film 206, the thickness of the portion located between the electrode film 103 and the bottom oxide film 207 is 2.5 nm. The thickness of the portion located between the interelectrode insulating film 104 and the bottom oxide film 207 is 4.7 nm.

The corner part of the block insulating film 201 on the memory hole 105 side faces toward the region between the cover oxide film 205 and the bottom oxide film 207.

Next, a method for manufacturing the semiconductor memory device 100 according to this embodiment is described.

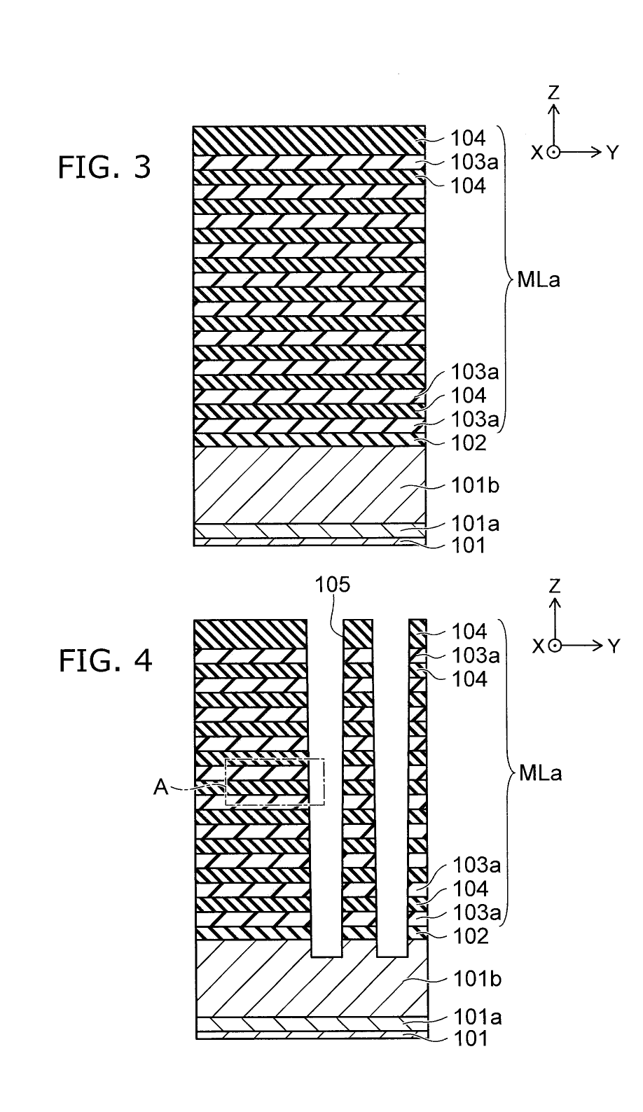

FIGS. 3 and 4 are process sectional views illustrating the method for manufacturing the semiconductor memory device 100 according to the embodiment.

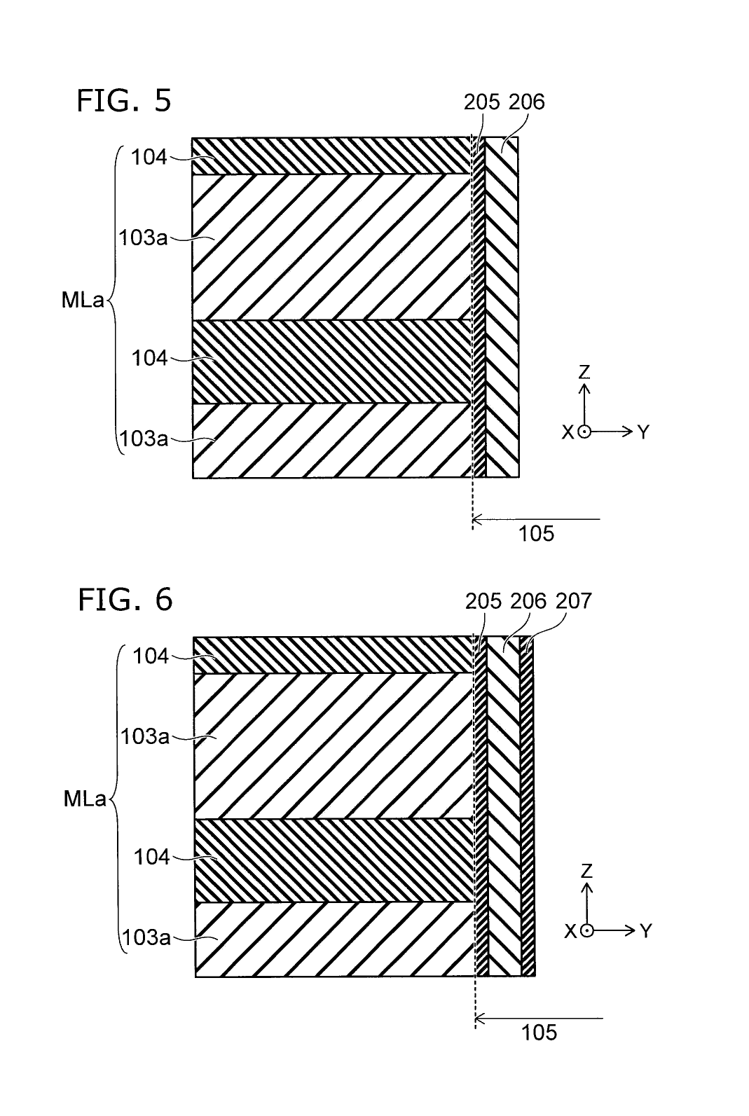

FIGS. 5 to 11 are process sectional views illustrating the method for manufacturing the semiconductor memory device according to the embodiment. FIGS. 5 to 11 show the region corresponding to portion B shown in FIG. 4.

First, as shown in FIG. 3, a semiconductor substrate 101 is prepared. The semiconductor substrate 101 is made of silicon. The conductivity type of the semiconductor substrate 101 is p⁻-type. Next, an impurity layer 101a is formed by ion implantation of donor impurity into the upper part of the semiconductor substrate 101.

An impurity layer 101b is formed by ion implantation of acceptor impurity into the upper part of the impurity layer 101a. Then, an interlayer insulating film 102 is formed on the upper surface of the impurity layer 101b.

A multilayer body MLa is formed by alternately stacking sacrificial films 103a and interelectrode insulating films 104 on the interlayer insulating film 102. The sacrificial film 103a is a first film. The multilayer body MLa is formed in e.g. 20 layers. The sacrificial film 103a is formed from silicon nitride film. The interelectrode insulating film 104 is formed from silicon oxide film.

Next, as shown in FIG. 4, a memory hole 105 is formed through the multilayer body MLa and the interlayer insulating film 102 by anisotropic etching such as RIE (reactive ion etching).

Next, as shown in FIG. 5, a cover oxide film 205 is formed by depositing silicon oxide on the inner surface of the memory hole 105 by ALD (atomic layer deposition). A silicon nitrogen-containing film 206 is formed on the side surface of the cover oxide film 205. At this time, the cover oxide film 205 and the silicon nitrogen-containing film 206 are formed also on the bottom surface of the memory hole 105.

Next, as shown in FIG. 6, the portion including the side surface of the silicon nitrogen-containing film 206 in the memory hole 105 is oxidized. Thus, a bottom oxide film 207 is formed. The oxidation of the portion including the side surface of the silicon nitrogen-containing film 206 is performed by an oxidation method such as radical oxidation, plasma oxidation, or ISSG (in-situ steam generation) oxidation. At this time, part of the silicon nitrogen-containing film 206 at the bottom surface part of the memory hole 105 is also oxidized. Thus, a bottom oxide film 207 is formed.

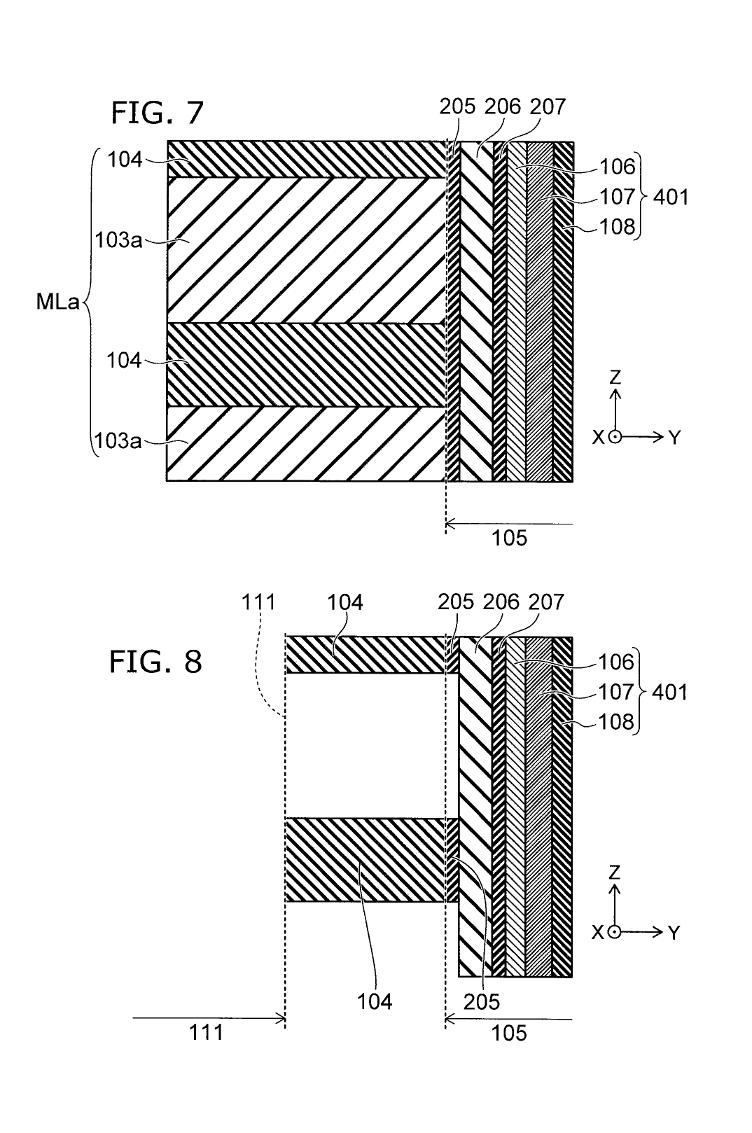

Next, as shown in FIG. 7, a semiconductor film 106 constituting a channel is formed on the side surface of the memory hole 105. The semiconductor film 106 is formed from a semiconductor material such as amorphous silicon. At this time, the semiconductor film 106 is formed also on the bottom surface of the memory hole 105. However, the cover oxide film 205, the silicon nitrogen-containing film 206, and the bottom oxide film 207 are interposed between the semiconductor film 106 and the impurity layer 101b. Thus, the semiconductor film 106 is not connected to the impurity layer 101b.

Subsequently, the semiconductor film 106, the bottom oxide film 207, the silicon nitrogen-containing film 206, and the cover oxide film 205 formed on the bottom surface of the memory hole 105 are removed by RIE (not shown). Thus, the impurity layer 101b is exposed at the bottom surface of the memory hole 105. Then, a semiconductor film 107 is formed as body silicon on the side surface of the semiconductor film 106 in the memory hole 105 and on the bottom surface of the memory hole 105. Thus, the semiconductor film 107 is connected to the impurity layer 101b. The semiconductor film 107 is formed from a semiconductor material such as amorphous silicon. Subsequently, silicon oxide is embedded inside the memory hole 105. Thus, a core oxide material 108 is formed.

Next, as shown in FIG. 8, a slit 111 is formed by anisotropic etching such as RIE. The slit 111 extends in the X-direction and penetrates through the multilayer body MLa. Subsequently, the sacrificial film 103a is removed by wet etching through the slit 111. This wet etching is performed using chemicals such as hot phosphoric acid. At this time, in the case where the sacrificial film 103a is formed from silicon nitride, the cover oxide film 205 serves as an etching stopper in the etching with hot phosphoric acid. This can prevent etching of the silicon nitrogen-containing film 206. Subsequently, the portion of the cover oxide film 205 exposed to the space formed by the removal of the sacrificial film 103a is removed by wet etching through the slit 111. This wet etching is performed using chemicals such as dilute hydrofluoric acid. Thus, part of the silicon nitrogen-containing film 206 that has been covered with the cover oxide film 205 is exposed. Furthermore, the surface layer of the interelectrode insulating film 104 is stripped when the cover oxide film 205 is removed.

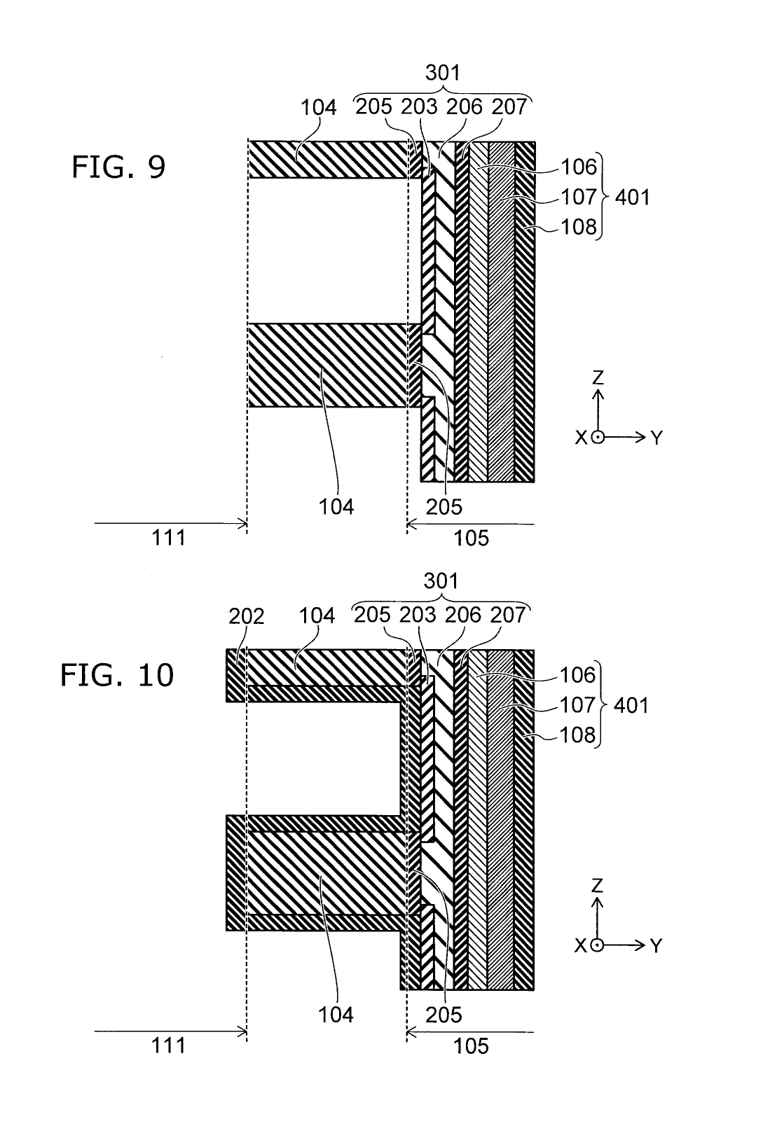

Next, as shown in FIG. 9, the portion including the exposed surface of the silicon nitrogen-containing film 206 is oxidized through the slit 111. This oxidation is performed by an oxidation method such as radical oxidation, plasma oxidation, or ISSG oxidation. Thus, the portion including the exposed surface of the silicon nitrogen-containing film 206 is oxidized into a top oxide film 203. Accordingly, a tunnel insulating film 301 is formed from the top oxide film 203, the cover oxide film 205, the silicon nitrogen-containing film 206, and the bottom oxide film 207. At this time, nitrogen contained in the oxidized portion of the silicon nitrogen-containing film 206 is ejected as N₂.

Next, as shown in FIG. 10, a charge accumulation film 202 is formed on the upper surface, on the lower surface, and on the side surface on the slit 111 side of the interelectrode insulating film 104, and on the side surface of the top oxide film 203 by depositing e.g. silicon oxide through the slit 111.

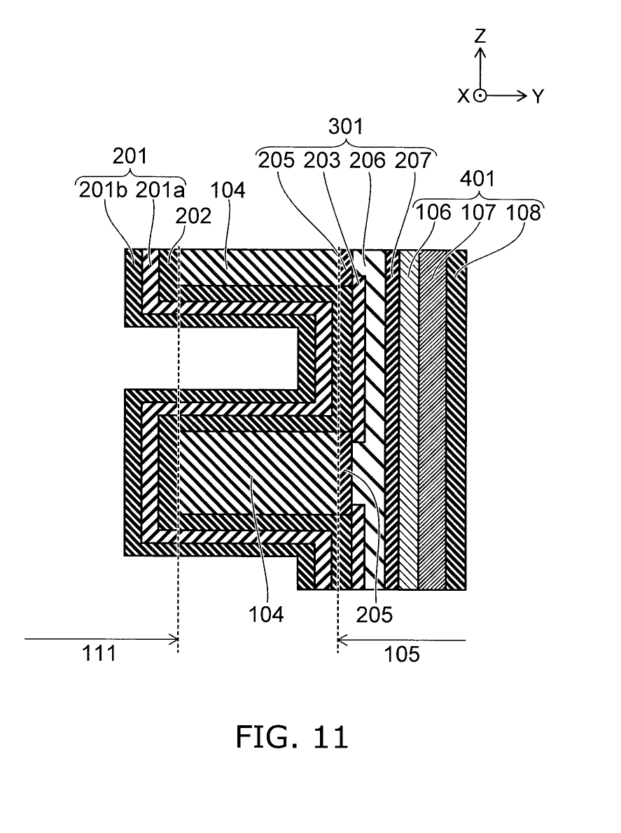

Next, as shown in FIG. 11, a block insulating film 201 is formed on the side surface on the slit 111 side of the charge accumulation film 202. The block insulating film 201 is formed by e.g. forming an insulating layer 201a including silicon oxide on the charge accumulation film 202 and stacking an insulating layer 201b including alumina on the insulating layer 201a.

Next, as shown in FIG. 2, a metal material such as tungsten (W) is embedded in the slit 111. This metal material is embedded also between the interelectrode insulating films 104 adjacent in the Z-direction, i.e., in the space formed by the removal of the sacrificial film 103a (see FIG. 7). Subsequently, the metal material is removed from the slit 111 by anisotropic etching such as RIE. At this time, the metal material is left between the interelectrode insulating films 104 adjacent in the Z-direction. The remaining metal material constitutes an electrode film 103.

Subsequently, the normal process is performed to manufacture the semiconductor memory device 100 according to this embodiment.

Next, the effect of this embodiment is described.

In the semiconductor memory device 100 according to this embodiment, as shown in FIG. 2, the tunnel insulating film 301 extends in a straight line along the Z-direction. However, the charge accumulation film 202 is located close to the tunnel insulating film 301 between the electrode film 103 and the tunnel insulating film 301, i.e., in the cell section. On the other hand, the charge accumulation film 202 is separated away from the tunnel insulating film 301 between the cell sections, i.e., in the interlayer section. This can suppress that the trapped charge in the charge accumulation film 202 is released through the silicon nitrogen-containing film 206 of the tunnel insulating film 301 to the channel region even if the trapped charge is diffused in the Z-direction. Thus, the data retention characteristics of the memory cell are improved.

Furthermore, as shown in FIG. 5, the cover oxide film 205 is formed by ALD. In this case, the etching rate of the cover oxide film 205 in the wet etching step shown in FIG. 8 is higher than that of the interelectrode insulating film 104. Thus, when removing the portion of the cover oxide film 205 exposed to the space formed by the removal of the sacrificial film 103a, the cover oxide film 205 is etched more preferentially than the interelectrode insulating film 104. Accordingly, the end surface of the cover oxide film 205 is set back with respect to the upper surface and the lower surface of the interelectrode insulating film 104. This forms a recess with the bottom surface being the end surface of the cover oxide film 205. Then, a charge accumulation film 202 and a block insulating film 201 are formed in the region from which the sacrificial film 103a and part of the cover oxide film 205 have been removed. Thus, the corner part of the block insulating film 201 is shaped so as to face toward the boundary of the cell section and the interlayer section. This shape causes electric field concentration in the interlayer section and increases the carrier concentration in the channel inversion layer of the memory cell transistor. In addition, in the central region of the interlayer section, the silicon nitrogen-containing film 206 is provided instead of the top oxide film 203 and has strong coupling with the channel composed of the semiconductor films 106 and 107. That is, the silicon nitrogen-containing film 206 can guide the electric field at the boundary of the cell section and the interlayer section to the center of the interlayer section because the silicon nitrogen-containing film 206 has higher permittivity than the top oxide film 203. This increases the amount of charge in the inversion layer induced in the channel portion of the interlayer section. Thus, the resistance of the interlayer section is decreased. This leads to the increase of the cell current of the NAND string. Thus, the operation of the semiconductor memory device 100 is stabilized.

Furthermore, the top oxide film 203 and the bottom oxide film 207 are formed by oxidizing part of the silicon nitrogen-containing film 206. In this case, the Si—N bond originally included in the silicon nitrogen-containing film 206 is replaced by a Si—O bond by oxidation. Thus, the structure of the lattice is continuous at the interface between the silicon nitrogen-containing film 206 and the top oxide film 203 and the interface between the silicon nitrogen-containing film 206 and the bottom oxide film 207. Accordingly, the number of dangling bonds is small. Thus, a good interface achieving lattice matching is formed.

For instance, the amount of lattice defects at the interface between the top oxide film 203 and the silicon nitrogen-containing film 206 is smaller than the amount of lattice defects at the interface between the cover oxide film 205 formed by depositing silicon oxide film and the silicon nitrogen-containing film 206. In addition, the number of defects in the top oxide film 203 and the bottom oxide film 207 formed by oxidizing part of the silicon nitrogen-containing film 206 is smaller than that of the top oxide film 203 and the bottom oxide film 207 formed by depositing oxide film. This decreases the amount of charge trapped in the tunnel insulating film 301 when the data write/erase operation is repeated. As a result, the durability characteristics and the data retention characteristics of the memory cell are improved.

In the above manufacturing method, the semiconductor memory device 100 under manufacturing may be annealed between arbitrary steps in order to improve the film quality of the deposited insulating film.

In the step of forming the cover oxide film 205 shown in FIG. 5, the cover oxide film 205 may be formed by oxidizing the sacrificial film 103a in the memory hole 105. In this case, the cover oxide film 205 is formed on the side surface of the sacrificial film 103a. However, the cover oxide film 205 is not formed on the side surface of the interelectrode insulating film 104. At this time, the oxidation of the portion including the side surface of the memory hole 105 in the multilayer body MLa is performed by an oxidation method such as radical oxidation, plasma oxidation, or ISSG oxidation.

Furthermore, in the case of forming the sacrificial film 103a from silicon nitride, it is difficult to ensure a sufficient etching selection ratio between the sacrificial film 103a and the silicon nitrogen-containing film 206 in the step of removing the sacrificial film 103a by wet etching shown in FIG. 8. Thus, in the embodiment, the cover oxide film 205 is formed as an etching block for the silicon nitrogen-containing film 206. However, the cover oxide film 205 does not need to be formed in the case where the sacrificial film 103a can be selectively removed even if the cover oxide film 205 is not provided. For instance, this is the case where the sacrificial film 103a is formed from a material capable of ensuring a sufficient etching selection ratio with respect to the silicon nitrogen-containing film 206.

The embodiments described above can realize a semiconductor memory device having high data retention characteristics and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a multilayer body including a plurality of electrode films separately stacked each other and a plurality of interelectrode insulating films disposed between the plurality of electrode films;
a semiconductor body that penetrates the multilayer body, extends in stacking direction of the multilayer body;
a charge accumulation film provided between the semiconductor body and the electrode film;
a top oxide film provided between the semiconductor body and the charge accumulation film and containing silicon and oxygen;
a silicon nitrogen-containing film provided between the semiconductor body and the interelectrode insulating film and between the semiconductor body and the top oxide film and containing silicon and nitrogen;
a bottom oxide film provided between the semiconductor body and the silicon nitrogen-containing film and containing silicon and oxygen; and
a block insulating film provided between the electrode film and the charge accumulation film,
in the silicon nitrogen-containing film, thickness of a portion located between the electrode film and the body being thinner than thickness of a portion located between the interelectrode insulating film and the body.

2. The device according to claim 1, wherein the charge accumulation film is provided also on an upper surface, on a lower surface, and on a side surface on opposite side from the semiconductor body side of the interelectrode insulating film.

3. A semiconductor memory device comprising:
a substrate;
a multilayer body provided on the substrate and including a plurality of electrode films separately stacked each other and a plurality of interelectrode insulating films disposed between the plurality of electrode films, a hole and a slit extending in stacking direction of the electrode films and the interelectrode insulating films being formed in the multilayer body;
a charge accumulation film provided between the interelectrode insulating film and the electrode film, between the interelectrode insulating film and the slit, and between the electrode film and the hole;
a block insulating film provided on a side surface on the slit side of the charge accumulation film;
a top oxide film provided on a side surface of the charge accumulation film in the hole and containing silicon and oxygen;
a silicon nitrogen-containing film provided on a side surface of the interelectrode insulating film and on a side surface of the top oxide film in the hole and containing silicon and nitrogen;
a bottom oxide film provided on a side surface of the silicon nitrogen-containing film in the hole and containing silicon and oxygen; and
a semiconductor film provided on a side surface of the bottom oxide film in the hole,
in the silicon nitrogen-containing film, thickness of a portion located between the electrode film and the bottom oxide film being thinner than thickness of a portion located between the interelectrode insulating film and the bottom oxide film.

4. The device according to claim 3, further comprising:
a cover oxide film provided between the interelectrode insulating film and the silicon nitrogen-containing film.

5. The device according to claim 3, wherein the bottom oxide film is made by oxidizing the silicon nitrogen-containing film.

6. The device according to claim 3, wherein
a corner part is formed in the block insulating film, and
the corner part faces toward a portion of the semiconductor film surrounded with the interelectrode insulating film.

7. The device according to claim 3, wherein the block insulating film includes a first insulating layer and a second insulating layer made of mutually different materials.

8. The device according to claim 7, wherein
the first insulating layer includes alumina, and
the second insulating layer includes silicon oxide.

9. The device according to claim 7, wherein the first insulating layer is provided between the electrode film and the second insulating layer.

10. A method for manufacturing a semiconductor memory device, comprising:
forming a multilayer body by alternately stacking first films and interelectrode insulating films on a substrate;
forming a hole penetrating through the multilayer body;
forming a silicon nitrogen-containing film containing silicon and nitrogen on a side surface of the hole;
forming a bottom oxide film by oxidizing an exposed portion of the silicon nitrogen-containing film in the hole;
forming a semiconductor film on a side surface of the bottom oxide film in the hole;
forming a slit penetrating through the multilayer body;
removing the first film through the slit;
forming a top oxide film by oxidizing part of the silicon nitrogen-containing film exposed by removal of the first film;
forming a charge accumulation film on an exposed surface of the interelectrode insulating film and the top oxide film through the slit;
forming a block insulating film on an exposed surface of the charge accumulation film; and
forming an electrode film between two of the interelectrode insulating films adjacent in stacking direction of the multilayer body on an exposed surface of the block insulating film.

11. The method according to claim 10, wherein the first film includes silicon nitride, and the method further comprises:
depositing a silicon oxide film on a side surface on the hole side of the first film; and
removing part of the silicon oxide film through a space formed by the removal of the first film after the removing the first film.

12. The method according to claim 10, wherein the first film includes silicon nitride, and the method further comprises:
forming a silicon oxide film by oxidizing a portion including a side surface on the hole side of the first film; and
removing at least part of the silicon oxide film through a space formed by the removal of the first film.

13. The method according to claim 10, wherein the forming the top oxide film includes performing radical oxidation.

14. The method according to claim 10, wherein the forming the top oxide film includes performing plasma oxidation.

15. The method according to claim 10, wherein the forming the top oxide film includes performing ISSG oxidation.

16. The method according to claim 10, wherein the forming the bottom oxide film includes performing radical oxidation.

17. The method according to claim 10, wherein the forming the bottom oxide film includes performing plasma oxidation.

18. The method according to claim 10, wherein the forming the bottom oxide film includes performing ISSG oxidation.

19. The method according to claim 10, wherein the forming the block insulating film includes:
forming a first insulating layer; and
forming a second insulating layer made of a material different from a material of the first insulating layer.

20. The method according to claim 19, wherein
the first insulating layer is a layer including alumina, and
the second insulating layer is a layer including silicon oxide.
